(19) United States
(12) Patent Application Publication
(10) Pub. No.: US 2006/0114012 A1
(43) Pub. Date: Jun. 1, 2006

(54) Method and apparatus for testing semiconductor wafers by means of a probe card

(76) Inventor: Erich Reitinger, Munchen (DE)

Correspondence Address: MOORE & VAN ALLEN PLLC, P.O. BOX 13706, Research Triangle Park, NC, 27709, US

(21) Appl. No.: 11/038,017

(22) Filed: Jan. 18, 2005

(30) Foreign Application Priority Data
Nov. 26, 2004 (DE) 10 2004 057 215.1

(51) Int. Cl. G01R 31/02

(52) U.S. Cl. 324/760

(57) ABSTRACT

The present invention provides a method for testing semiconductor wafers (5) by means of a probe card (7; 7′, 7′a; 7″), comprising the following steps: providing a temperature-controlled chuck device (1); laying the rear side (R) of a semiconductor wafer (5) on a supporting side (AF) of the temperature-controlled chuck device (1); placing the probe card (7; 7′, 7′a; 7″) on the front side (O) of the semiconductor wafer (5); impressing a current into a chip region of the front side (O) of the semiconductor wafer (5) by means of probes (91-94) of the chip card (7; 7′, 7′a; 7″) placed on; and directing a focused temperature-controlled fluid jet (G) onto the front side (O) of the semiconductor wafer (5), by which means a temperature of the chip region is kept substantially at a temperature of the supporting side (AF) of the temperature-controlled chuck device (1). The present invention likewise provides a corresponding apparatus for testing semiconductor wafers (5) by means of a probe card (7).

The present invention relates to a method and apparatus for testing semiconductor wafers by means of a probe card.

As is known, test measurements on semiconductor wafers are typically carried out in a temperature range between −60° C. and +400° C. For the purpose of temperature control, a semiconductor wafer is laid on a prober table or chuck, which is cooled and/or heated in accordance with the desired temperature.

In this case, it is firstly necessary to take care that the temperature of the semiconductor wafer does not fall below the dew point of the surrounding gaseous medium, since otherwise condensation of moisture occurs on the semiconductor wafer surface, or icing, which hampers the test measurements or makes them impossible.

Secondly, in the case of test measurements with a high chip power, the problem arises that, in the region of the current flow, the semiconductor wafer is heated locally on the front side above the temperature of the rear side in contact with the chuck since, because of the finite heat transfer resistance between semiconductor wafer and chuck, the dissipation of heat is delayed. Typically, in the case of electrical powers of about 100 W, a local temperature difference of about 90 K between the front side of the semiconductor wafer and the supporting side of the chuck is obtained. This temperature difference disrupts the test measurement, which in particular is intended to specify the isothermal electrical properties of the circuits integrated in the semiconductor wafer. At the same time, at relatively high powers the chips can be heated above a maximum permitted temperature, which is associated with the risk of electrical failure.

FIG. 7 shows a schematic cross-sectional view of an apparatus disclosed by U.S. Pat. No. 5,010,296 for testing semiconductor wafers by means of a probe card.

In FIG. 7, reference symbol 6′ designates a chuck device of which the temperature can be controlled. The chuck device 6′ is connected to a drive device 7′, which can bring about a movement in the vertical direction and the plane. Provided above the chuck device 6′ is a probe card 12′, which has probes 1′, for example in the form of fine needles, which are used for the purpose of making contact with integrated circuits on a semiconductor wafer 30′ and carrying out electrical measurements thereon.

Reference symbol 13′ designates a test device, by means of which the probes 1′ can be driven in accordance with predefined test programmes. Likewise capable of being driven by the test device 13′ is the control device 7′, in order to connect specific integrated circuits of the semiconductor wafer 30′ to the probes 1′.

A gas feed device 8′, which is connected to a gas supply device 10′, is provided on one side of the chuck device 6′.

On the opposite side of the chuck device 6′, a suction line device 9′ is provided, which is in turn connected to a suction device 11′. The gas feed device 8′ and the suction line device 9′ have a relatively flat cross-sectional shape, so that gas can be flushed uniformly over the entire surface of the semiconductor wafer 30′. The gas flush in this known semiconductor wafer testing apparatus is used to transport away contamination particles which are deposited on the surface of the semiconductor wafer as a result of external influences or under the influence of the probes 1′.

The structure of probe cards for testing semiconductor wafers is known from Elektronik, Produktion und Prüftechik [Electronics, Production and Testing Technology], July/August 1982, pages 485 to 487, Positionieren und Kontaktieren von Halbleiterwafern [Positioning and making contact with semiconductor wafers].

EP 0 438 957 B1 discloses a testing apparatus for semiconductor-semiconductor wafers, a large number of temperature sensors being fitted to a chuck device, which register a corresponding temperature distribution on the chuck surface.

EP 0 511 928 B1 discloses a chuck device having a large number of labyrinth channels, through which a fluid for the temperature control of the chuck device is led. As a result of the labyrinthine structure, a high cooling capacity and a homogeneous temperature distribution are achieved.

The object of the present invention is to specify a method and an apparatus for testing semiconductor wafers by means of a probe card which permit more efficient conditioning of the semiconductor wafer.

The method according to the invention, having the features of claim 1, and the corresponding apparatus according to claim 11 have the advantage as compared with the known approach to a solution that, even with a high electrical power, only a very low temperature difference arises between the front side of the semiconductor wafer and the supporting side of the chuck.

The idea on which a first invention is based is that a device for directing a focused temperature-controlled fluid jet onto the front side of the semiconductor wafer is provided, by which means the temperature of the chip to be tested can be kept substantially at the temperature of the supporting side of the chuck.

The idea on which a second invention is based is that the probes of the probe card have their temperature controlled by an independent temperature control device.

The idea on which a third invention is based is that the focused temperature-controlled fluid jet is directed onto the front side of the semiconductor wafer by means of a variable-length nozzle device.

The idea on which a fourth invention is based is that the temperature on the front side of the semiconductor wafer is registered by a non-contact temperature registering device.

Advantageous developments and improvements of the relevant subject of the invention will be found in the subclaims.

According to a preferred development, the focused temperature-controlled fluid jet is directed onto the front side of the semiconductor wafer by means of a nozzle device which is fitted to the probe card.

According to a further preferred development, the nozzle device is fitted to a side of the probe card facing away from the semiconductor wafer.

According to a further preferred development, the nozzle device is integrated into the probe card.

According to a further preferred development, the probes of the probe card have their temperature controlled by a temperature control device which is independent of the fluid jet and which is fitted to the probe card.

According to a further preferred development, the focused temperature-controlled fluid jet is directed onto the front side of the semiconductor wafer by means of a variable-length nozzle device, a distance between an outlet of the nozzle device being set automatically by a fluid cushion above the chip region.

According to a further preferred development, the temperature of the chip region is registered by a non-contact temperature registering device fitted above the chip region.

According to a further preferred development, a further fluid flows through the chuck device, of which the temperature difference between outlet temperature and inlet temperature is registered and used to regulate at least one of the following variables: temperature of the chuck device, temperature of the fluid jet, temperature of the probes.

Exemplary embodiments of the invention are illustrated in the drawings and explained in more detail in the following description.

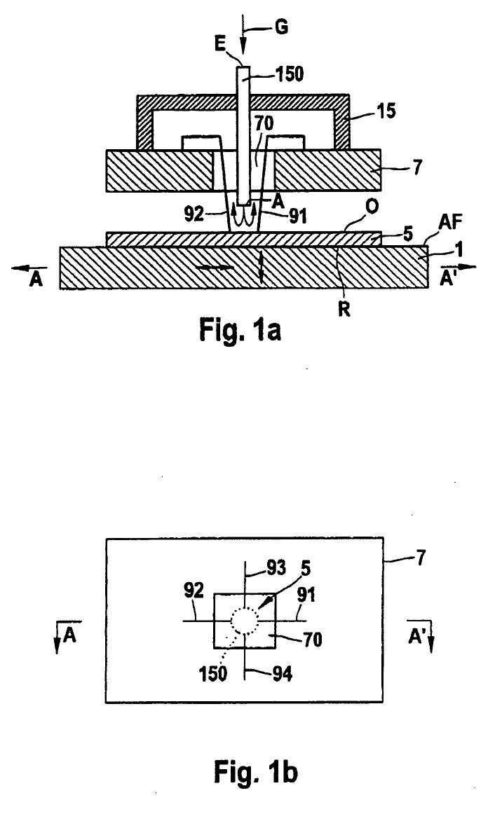

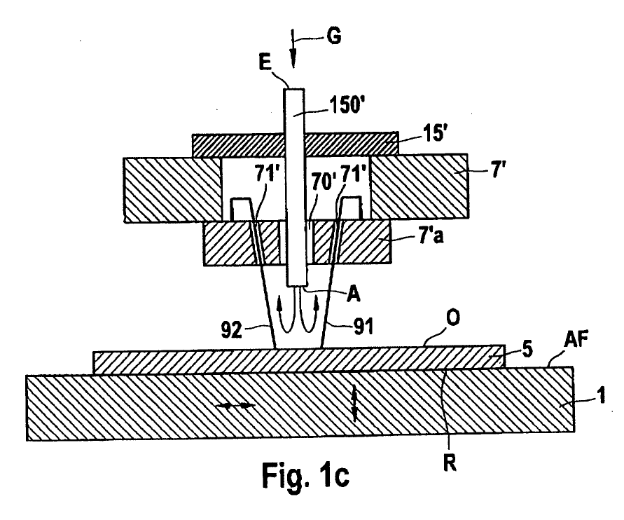

FIGS. 1a, b show schematic illustrations of a first embodiment of the apparatus according to the invention for testing semiconductor wafers by means of a probe card, specifically FIG. 1a in cross section and FIG. 1b in plan view;

FIG. 1c shows a modification of the first embodiment with regard to the probe card;

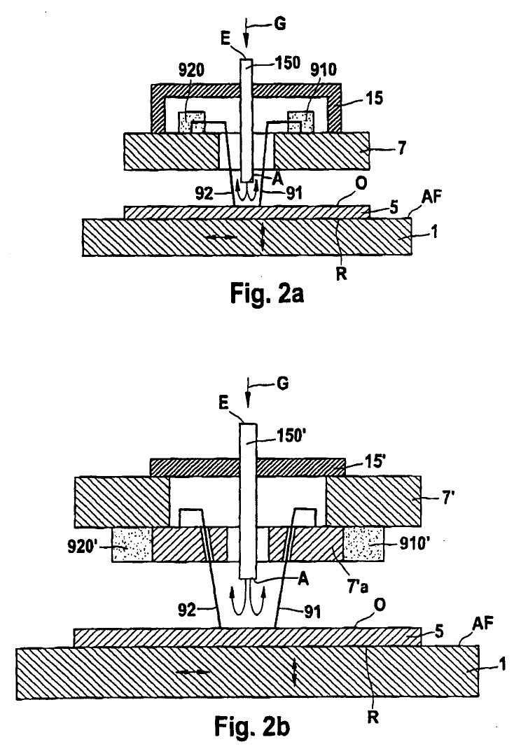

FIG. 2a shows a schematic illustration of a second embodiment of the apparatus according to the invention for testing semiconductor wafers by means of a probe card;

FIG. 2b shows a modification of the second embodiment with regard to the probe card;

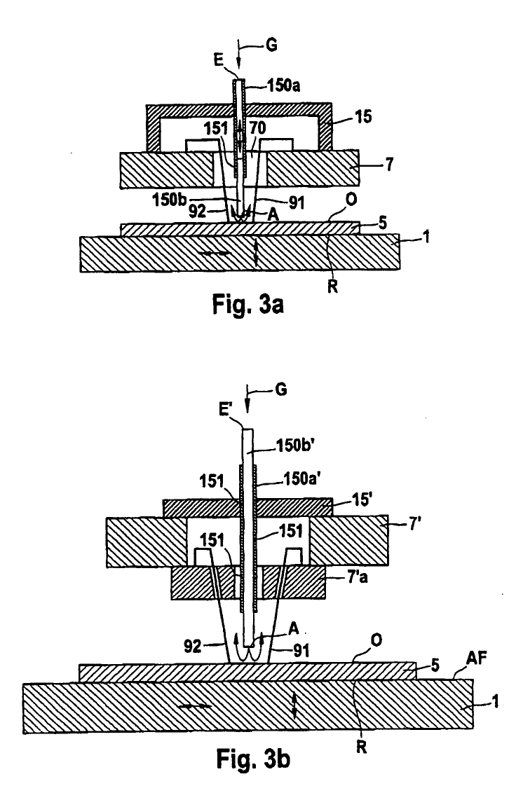

FIG. 3a shows a schematic cross-sectional view of a third embodiment of the apparatus according to the invention for testing semiconductor wafers by means of a probe card;

FIG. 3b shows a modification of the third embodiment with regard to the probe card;

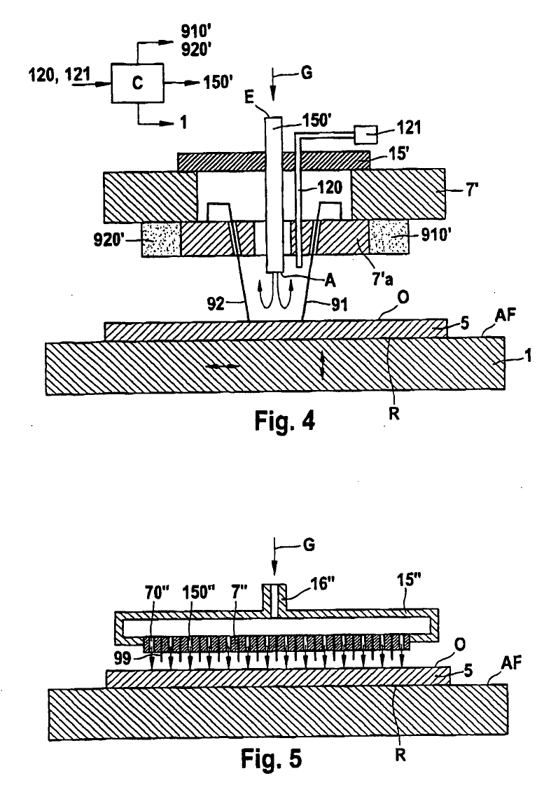

FIG. 4 shows a schematic cross-sectional view of a fourth embodiment of the apparatus according to the invention for testing semiconductor wafers by means of a probe card;

FIG. 5 shows a schematic cross-sectional view of a fifth embodiment of the apparatus according to the invention for testing semiconductor wafers by means of a probe card;

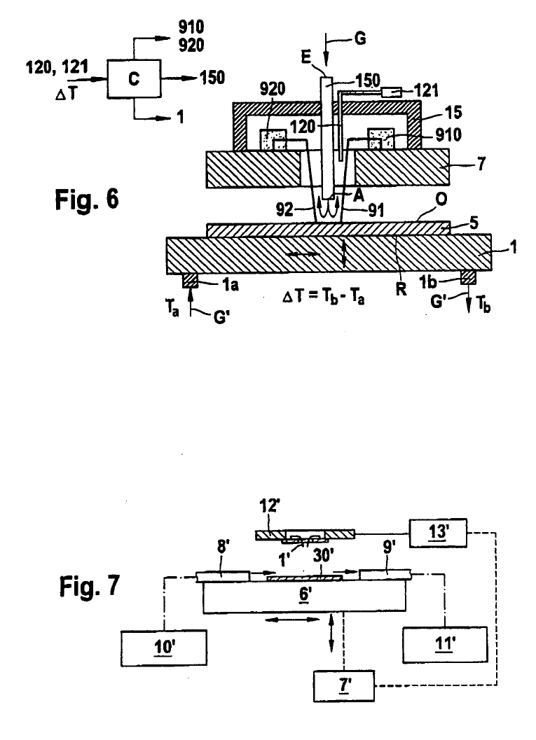

FIG. 6 shows a schematic cross-sectional view of a sixth embodiment of the apparatus according to the invention for testing semiconductor wafers by means of a probe card; and

FIG. 7 shows a schematic cross-sectional view of an apparatus disclosed by U.S. Pat. No. 5,010,296 for testing semiconductor wafers by means of a probe card.

In the figures, identical reference symbols designate identical or functionally identical constituent parts.

FIGS. 1a, b show schematic illustrations of a first embodiment of the apparatus according to the invention for testing semiconductor wafers by means of a probe card, specifically FIG. 1a in cross-section along the line A-A′ and FIG. 1b in plan view.

In FIGS. 1a, b, reference symbol 1 designates a chuck device of which the temperature can be controlled and which can be moved in the vertical direction and within the plane. On the chuck device 1 there is a semiconductor wafer 5 which, with its rear side R, makes contact with the supporting side AF of the chuck device 1, in which vacuum grooves, not illustrated, are provided for attraction by suction. By means of a temperature control system, not illustrated, the chuck device 1 is kept at a predefined temperature and this is transmitted to the semiconductor wafer 5. Above the semiconductor wafer 5 there is a plate-like probe device 7, on the side of which facing away from the semiconductor wafer 5 probes 91 to 94 are anchored and connected electrically, the probes 91 to 94 being led through a passage opening 70 in the probe device 7 and being placed on an integrated circuit (chip region) on the front side O of the semiconductor wafer 5.

By means of a tester device, not illustrated, electrical test sequences are transmitted to the integrated circuit via the probes 91 to 94. In order to avoid the disruptive local heating mentioned at the beginning in a chip region on the front side O of the semiconductor wafer 5, a nozzle device 150, which has an inlet E and an outlet A, is likewise led through the passage opening 70. Through the nozzle device 150, a fluid G with a predefinable temperature, for example temperature-controlled, dried air, is directed absolutely vertically onto the front side O of the semiconductor wafer 5 from a short distance. The nozzle device 150 is anchored on the side of the probe device 7 facing away from the semiconductor wafer 5 by means of a holding device 15.

By means of this structure, it is possible to achieve the situation where no local heating of the chip region occurs even at high powers of typically more than 100 W since, by means of the fluid G, the heat can also be dissipated from the front side O of the semiconductor wafer 5 and not just from the rear side R by means of the chuck device 1.

FIG. 1c shows a modification of the first embodiment with regard to the probe card.

Whereas, according to FIG. 1a, the probe card 7 had a plate shape and the probe needles 91 to 94 originated from its side away from the wafer, the probe card according to FIG. 1c has a plate-like region 7′ and a stepped region 7′a attached to the underside, the probe needles 91-94 being anchored in the stepped region 7′a. Here, too, the probe needles 91 to 94 are led through passage openings 71′, which are different from a passage opening 70′ through which the nozzle device 150′ is led. The holding device 15′ in this modification of the first embodiment is placed in the shape of a plate on the upper side of the plate-like region 7′.

FIG. 2a shows a schematic illustration of a second embodiment of the apparatus according to the invention for testing semiconductor wafers by means of a probe card.

With reference to FIG. 2a, on the side of the probe device facing away from the semiconductor wafer 5 there is additionally provided an independent further temperature control device 910, 920, which is in direct thermal contact with the probes 91, 92. Thus, heat can additionally be dissipated directly by the probes 91 to 94, which further counteracts heating of the front side O of the semiconductor wafer 5 in the chip region. In the present example, the temperature control device 910, 920 is a porous heat exchanger device which is operated with a temperature-controlled liquid.

FIG. 2b shows a modification of the second embodiment with regard to the probe card.

The modification shown in FIG. 2b corresponds to the example according to FIG. 1c with regard to the configuration of the probe card. However, an independent further temperature control device 910′, 920′ is also provided here, which surrounds the stepped region 7′a of the probe device annularly and is likewise a porous heat exchanger device which is operated with a temperature-controlled liquid.

FIG. 3a shows a schematic cross-sectional view of a third embodiment of the apparatus according to the invention for testing semiconductor wafers by means of a probe card.

In the embodiment shown in FIG. 3a, the nozzle device 150a, 150b is in two parts. The upper part 150a of the nozzle device is connected to the holding device 15, which is fitted to the side of the probe device 7 facing away from the semiconductor wafer 5. The lower part 150b of the nozzle device is plugged into the upper part 150a such that it can be displaced, a sealing device 151 preventing the fluid G emerging at this point during displacement. In this embodiment, the distance between the outlet A of the lower part 150b of the nozzle device and the chip region is set automatically by a fluid cushion above the chip region. This has the advantage that the temperature control is still more effective, since the distance is minimized in a self-adjusting manner.

FIG. 3b shows a modification of the third embodiment with regard to the probe card.

The modification according to FIG. 3b likewise goes back to the example according to FIG. 1c, the nozzle device 150a′, 150b′ here comprising an outer sleeve 150a′ which is fitted to the holding device 15′. Led through the outer sleeve 150a′ is an inner tube 150b′ having an inlet E′ and an outlet A′ for the fluid G. Interposed between the outer sleeve 150a′ and the inner tube 150b′, as in the embodiment according to FIG. 3a, is a sealing device 151, for example in the form of a plurality of sliding rings. In this example, too, the distance between the outlet A′ and the front side O of the semiconductor wafer 5 can be set automatically in a self-adjusting manner.

FIG. 4 shows a schematic cross-sectional view of a fourth embodiment of the apparatus according to the invention for testing semiconductor wafers by means of a probe card.

The structure according to FIG. 4 corresponds to that according to FIG. 2b with the exception of the differences described below.

In the fourth embodiment, shown in FIG. 4, in addition to the nozzle device 150′, a non-contact temperature registering device 120, 121 is additionally provided which, in this example, is formed as an infrared thermometer (IR). The non-contact temperature registering device 120, 121 comprises an IR optical waveguide 120 and an evaluation circuit 121 which, by means of an IR photoconductor, not shown, and an amplifier connected downstream, registers the temperature in the chip region directly, so that this temperature can be used as a control parameter for a controller device C which, in turn, regulates the temperature of the chuck device 1, of the fluid G in the nozzle device 150′ and of the temperature control device 910′, 920′ for the probes 91 to 94.

FIG. 5 shows a schematic cross-sectional view of a fifth embodiment of the apparatus according to the invention for testing semiconductor wafers by means of a probe card.

In the embodiment shown in FIG. 5, the nozzle device 150″ is integrated into the plate-like probe device 7″ in the form of many small channels 70″, which run between the probe needles 99. In this example, a hood 15″ having a connecting piece 16″ for feeding the temperature-controlled fluid G is placed on the probe device 7″.

In this probe device, in order to measure a chip, a sub-group of the probe needles 99 can be activated specifically. Because of the distribution of the channels 70″, however, the entire front side O of the semiconductor wafer 5 under the probe device 7″ always has its temperature controlled. This makes the temperature control still more effective since it acts not just at a point but even over an area.

FIG. 6 shows a schematic cross-sectional view of a sixth embodiment of the apparatus according to the invention for testing semiconductor wafers by means of a probe card.

In the fifth embodiment, shown in FIG. 6, an inlet 1a and an outlet 1b of the labyrinthine channel system, not shown, of the chuck device are shown.

Here, too, a non-contact temperature registering device 120, 121 comprising an IR optical waveguide 120 and an evaluation circuit 121 is provided, which registers the temperature in the chip region directly by means of an IR photoconductor, not shown, and an amplifier connected downstream, so that this temperature can be used as a control parameter for a controller device C which, in turn, regulates the temperature of the chuck device 1, of the fluid G in the nozzle device 150 and of the temperature control device 910, 920 for the probes 91 to 94.

In this embodiment, a temperature difference of a cooling fluid ΔT is additionally determined, which corresponds at the inlet 1a to a difference between a temperature Tb registered at the outlet 1b and a temperature Ta registered at the inlet 1a. The temperature difference registered in this way is input to the controller device C as a further control parameter.

Although the present invention has been described above by using preferred exemplary embodiments, it is not restricted thereto but can be modified in many ways.

In particular, the invention is not restricted to gaseous dried air but in principle can be applied to any desired fluids.

Although in the above embodiments the holding device 15 for the nozzle device 150 was provided on the side of the probe device facing away from the semiconductor wafer, this could of course in principle also be located on the side facing the semiconductor wafer. Other geometries and materials of the nozzle device and of the probes are also conceivable.

Furthermore, it is possible that the registered temperature of the chip region or the temperature difference at the outlet and inlet of the chuck device are not both used for regulation but only one variable. In addition, the regulation of the controller device does not need to act simultaneously on the chuck device, the fluid of the nozzle device and the independent temperature control device of the probes, instead regulation of an individual one of these devices or a sub-combination of these devices would also be imaginable.

1. Method for testing semiconductor wafers by means of a probe card, comprising the following steps:
providing a temperature-controlled chuck device;
laying a rear side of a semiconductor wafer on a supporting side of the temperature-controlled chuck device;
placing the probe card on a front side of the semiconductor wafer;
impressing a current into a chip region of the front side of the semiconductor wafer by means of probes of the probe card placed thereon; and
directing a focused temperature-controlled fluid jet onto the front side of the semiconductor wafer, by which means a temperature of the chip region is kept substantially at a temperature of the supporting side of the temperature-controlled chuck device.

2. Method according to claim 1, characterized in that the focused temperature-controlled fluid jet is directed onto the front side of the semiconductor wafer by means of a nozzle device, which is fitted to the probe card.

3. Method according to claim 2, characterized in that the nozzle device is fitted to a side of the probe card facing away from the semiconductor wafer.

4. Method according to claim 2, characterized in that the nozzle device is integrated into the probe card.

5. Method according to claim 1, characterized in that the probes of the probe card have their temperature controlled by a temperature control device which is independent of the fluid jet and which is fitted to the probe card.

6. Method according to claim 1, characterized in that the nozzle device has a variable-length and the focused temperature-controlled fluid jet is directed onto the front side of the semiconductor wafer by means of the variable-length nozzle device and a distance between an outlet of the nozzle device is set automatically by a fluid cushion above the chip region.

7. Method according to claim 1, characterized in that the temperature of the chip region is registered by a non-contact temperature registering device fitted above the chip region.

8. Method according to claim 1, characterized in that a further fluid flows through the chuck device, having a temperature difference between outlet temperature and inlet temperature wherein the temperature difference is registered and used to regulate at least one of the temperature of the chuck device, the temperature of the fluid jet, and the temperature of the probes.

9. Apparatus for testing semiconductor wafers by means of a probe card comprising:
a temperature-controlled chuck device having a supporting side for a rear side of a semiconductor wafer to be laid thereon;
the probe card to be placed on a front side of the semiconductor wafer and to impress a current into a chip region on the front side of the semiconductor wafer by means of probes of the probe card placed thereon; and
a device for directing a focused temperature-controlled fluid jet onto the front side of the semiconductor wafer, by which means a temperature of the chip region can be kept substantially at a temperature of the supporting side of the temperature-controlled chuck device.

10. Apparatus according to claim 9, characterized in that the focused temperature-controlled fluid jet can be directed onto the front side of the semiconductor wafer by means of a nozzle device, which is fitted to the probe card.

11. Apparatus according to claim 10, characterized in that the nozzle device is fitted to a side of the probe card facing away from the semiconductor wafer.

12. Apparatus according to claim 10, characterized in that the nozzle device is integrated into the probe card.

13. Apparatus according to claim 11, characterized in that the probes of the probe card can have their temperature controlled by a temperature control device which is independent of the fluid jet and which is fitted to the probe card.

14. Apparatus according to claim 9, characterized in that the nozzle device has a variable-length and the focused temperature-controlled fluid jet is directed onto the front side of the semiconductor wafer by means of the variable-length nozzle device and a distance between an outlet of the nozzle device is set automatically by a fluid cushion above the chip region.

15. Apparatus according to claim 9, characterized in that the temperature of the chip region is registered by a non-contact temperature registering device fitted above the chip region.

16. Apparatus according to claim 9, characterized in that a further fluid flows through the chuck device, having a temperature difference between outlet temperature and inlet temperature wherein the temperature difference is registered and used to regulate at least one of the temperature of the chuck device, the temperature of the fluid jet (G), and the temperature of the probes.
